(19) United States
(12) Patent Application Publication
(10) Pub. No.: US 2026/0173261 A1
(43) Pub. Date: Jun. 18, 2026

(54) CIRCUIT MODULE

(71) Applicant: Murata Manufacturing Co., Ltd., Nagaokakyo-shi (JP)

(72) Inventor: Hirofumi OIE, Nagaokakyo-shi (JP)

(73) Assignee: Murata Manufacturing Co., Ltd., Nagaokakyo-shi (JP)

(21) Appl. No.: 19/531,710

(22) Filed: Feb. 6, 2026

Related U.S. Application Data
(63) Continuation of application No. PCT/JP2024/040552, filed on Nov. 15, 2024.

(30) Foreign Application Priority Data
Dec. 4, 2023 (JP) 2023-204663

(51) Int. Cl. H05K 1/02; H05K 1/03; H05K 3/28

(52) U.S. Cl. CPC H05K 1/0296; H05K 1/0306; H05K 3/285

(57) ABSTRACT

A circuit module including a substrate having a first main surface and a second main surface, with a connection terminal disposed adjacent to the first main surface. The substrate includes a first electrode on or in the first main surface, and a first end of the connection terminal is bonded to the first electrode. When viewed in a thickness direction, the first electrode is defined by three distinct regions. A first portion is bonded to the connection terminal. A second portion surrounds an outer periphery of the first portion. A third portion surrounds an outer periphery of the second portion. A plating film is on a surface of the second portion. A ceramic protective film made of a ceramic material is on a surface of the third portion.

### CROSS-REFERENCE TO RELATED APPLICATIONS

This application is a Continuation of PCT Application No. PCT/JP2024/040552, filed on Nov. 15, 2024, which claims priority to Japanese Patent Application No. 2023-204663, filed Dec. 4, 2023, the entire contents of each of which are incorporated herein by reference.

### TECHNICAL FIELD

The present disclosure relates to circuit modules.

### BACKGROUND ART

Components installed in electronic devices include a circuit module where electronic components and the like are mounted on a substrate (e.g., LTCC substrate) and sealed with resin.

When a circuit module with electronic components mounted on both sides of a substrate is mounted on a board (mounting board) such as a motherboard, electrodes (external connection terminals or connection terminals) that penetrate a resin layer in its thickness direction are required to connect the substrate of the circuit module to the mounting board.

For example, Patent Literature 1 discloses a circuit module including: a substrate on one main surface of which a first electrode and a second electrode are provided; a first electronic component connected to the first electrode; and a first resin layer provided on the one main surface of the substrate, wherein the second electrode includes a second electrode base body connected to the substrate, a metal post, whose one end is directly connected to the second electrode base body and the other end is positioned in an inner side portion relative to the outer surface of the first resin layer, with the metal post including sintered metal powder, a plating film covering a lateral surface of the second electrode base body and the metal post, and a covering portion whose one main surface is connected to the other end of the metal post and the plating film and the other main surface is positioned in the outside portion relative to the outer surface of the first resin layer.

Patent Literature 1 discloses that a plating film that is compatible with the resin layer is disposed on a lateral surface of the metal post that constitutes the second electrode serving as an external connection terminal, and such a plating film can increase the adhesion between the metal post and the resin layer and prevent or reduce the separation therebetween.

### CITATION LIST

### Patent Literature

Patent Literature 1: JP 6791352 B

### SUMMARY

A circuit module includes: a substrate having a first main surface and a second main surface, with a first electrode on or in the first main surface. A connection terminal is positioned adjacent to the first main surface of the substrate, with a first end of the connection terminal bonded to the first electrode. When viewed in a thickness direction, the first electrode includes a first portion bonded to the connection terminal, a second portion surrounding an outer periphery of the first portion, and a third portion surrounding an outer periphery of the second. A plating film is on a surface of the second portion, and a ceramic protective film made of a ceramic material is on a surface of the third portion.

### Advantageous Effects

The present disclosure can provide a circuit module that can improve thermal cycle characteristics and connection reliability without being affected by the specifications of a mounting board.

### BRIEF DESCRIPTION OF DRAWINGS

FIG. 1 is a schematic top view of an example of a circuit module of the present disclosure.

FIG. 2 is a cross-sectional view taken along line A-A in FIG. 1.

FIG. 3 is a diagram illustrating the correspondence between a partially enlarged view of FIG. 2 and a schematic view of a bonding interface between a connection terminal and a first electrode, when viewed from a connection terminal side, in the enlarged view.

FIG. 4 is a diagram illustrating the correspondence between an enlarged view of a bonding portion between a connection terminal and a first electrode in another example of the circuit module of the present disclosure and a schematic view, when viewed from the connection terminal side, of the bonding interface between the connection terminal and the first electrode in the enlarged view.

FIG. 5 is a schematic cross-sectional view of an example of a constraining-layer sheet used to produce a circuit module.

FIG. 6 is a schematic cross-sectional view of printing a conductive paste on a surface of the constraining-layer sheet shown in FIG. 5.

FIG. 7 is a schematic cross-sectional view of forming through holes in the constraining-layer sheet shown in FIG. 5.

FIG. 8 is a schematic cross-sectional view of filling the through holes of the constraining-layer sheet shown in FIG. 7 with a conductive paste.

FIG. 9 is a schematic cross-sectional view of an example of a ceramic green sheet used to produce a circuit module.

FIG. 10 is a schematic cross-sectional view of printing a conductive paste on a surface of the ceramic green sheet shown in FIG. 9.

FIG. 11 is a schematic cross-sectional view of forming through holes in the ceramic green sheet shown in FIG. 9.

FIG. 12 is a schematic cross-sectional view of filling the through holes of the ceramic green sheet shown in FIG. 11 with a conductive paste.

FIG. 13 is a schematic cross-sectional view of printing a conductive paste on a surface of the ceramic green sheet shown in FIG. 12.

FIG. 14 is a schematic cross-sectional view of printing a conductive paste and a ceramic protective film paste on the surface of the ceramic green sheet shown in FIG. 12.

FIG. 15 is a schematic view of an example of stacking prepared lamination sheets.

FIG. 16 is a schematic view of an example of compression bonding of a stack.

FIG. 17 is a schematic view of an example of firing a compression-bonded body.

FIG. 18 is a schematic view of an example of removing a constraining layer.

FIG. 19 is a schematic view of an example of forming a plating film.

FIG. 20 is a schematic view of an example of mounting an electronic component on one main surface of a substrate.

FIG. 21 is a schematic cross-sectional view of an example of sealing the electronic component.

FIG. 22 is a schematic cross-sectional view of an example of grinding a sealing resin surface.

FIG. 23 is a schematic cross-sectional view of forming a plating film on a surface of each of connection terminals.

FIG. 24 is a schematic cross-sectional view of mounting electronic components on the other main surface of the substrate.

FIG. 25 is a schematic cross-sectional view of an example of sealing the electronic components.

FIG. 26 is a schematic cross-sectional view of an example of grinding a sealing resin surface.

### DESCRIPTION OF EMBODIMENTS

Hereinafter, circuit modules of the present disclosure are described. The present disclosure is not limited to the following embodiments and may be suitably modified without departing from the gist of the present disclosure. Combinations of two or more features described in the following embodiments are also within the scope of the present disclosure.

In the present specification, the terms indicating the relationship between elements (for example, “parallel”, “orthogonal”, and the like) are not expressions indicating only a strict meaning, but are expressions meaning to include a substantially equivalent range, for example, a difference of about several %. In the present disclosure, the term ‘adjacent’ as used to describe the relationship between structural elements (e.g., the connection terminal and the substrate surface, or the resin layer and the substrate) refers to a position that is immediately neighboring or in direct contact with the referenced surface or element, unless otherwise specified.

The figures illustrated below are schematic views, and dimensions, scales of aspect ratios, and the like may be different from those of actual products.

In recent years, electronic components have been increasingly required to be smaller and more reliable. However, the inventor has observed that smaller components are prone to cracking at the interface between a metal post and a substrate due to thermal cycling or impact when the housing is dropped.

Patent Literature 1 discloses that a plating film is disposed at the interface between a metal post, which serves as a connection terminal, and a resin layer to enhance adhesion between the metal post and the resin layer, but does not sufficiently prevent or reduce cracking between the substrate and the metal post that constitute the circuit module.

In general, the thermal stress generated in heterogeneous bonding such as bonding between a ceramic substrate and a metal post that has a large coefficient of thermal expansion can be reduced by using a smaller metal post. However, the area, shape, position, and other parameters of the connection terminals (metal posts) on the mounting surface are determined according to the specifications of the mounting board (those provided by the customer).

The specifications of the mounting board include the position, shape, and other parameters of the connection terminals for connection to the circuit module to be mounted on the mounting board. When a circuit module is mounted on a mounting board, the positions and shapes of the metal posts of the circuit module which serve as connection portions for connection to the mounting board have to be aligned with the positions and shapes of the connection terminals of the mounting board. Therefore, once the area, shape, position, and other parameters of the connection terminals (metal posts) have been determined as the specifications of the mounting board, they cannot be changed to improve the thermal cycle characteristics or connection reliability due to the convenience of the circuit module.

For these reasons, there has been a demand for improving thermal cycle characteristics and connection reliability without being affected by the specifications of a mounting board.

Because these specifications are fixed, the metal posts of the circuit module must align with the connection terminals of the mounting board and cannot easily be changed to improve thermal cycle characteristics or connection reliability. The inventor has discovered that by partitioning the electrode into specific portions and applying different protective layers (plating and ceramic) as described herein, thermal cycle characteristics and connection reliability can be improved without being restricted by the external specifications of a mounting board. The present disclosure is directed to providing a circuit module that can improve thermal cycle characteristics and connection reliability without being affected by the specifications of a mounting board.

### Circuit Module

The circuit module of the present disclosure includes: a substrate having one main surface and an other main surface; and a connection terminal disposed adjacent to the one main surface of the substrate, wherein the substrate includes a first electrode on or in the one main surface, and one end of the connection terminal adjacent to the one main surface of the substrate is bonded to the first electrode, and wherein in the first electrode when viewed in a thickness direction, a portion of the first electrode bonded to the connection terminal is defined as a first portion, a portion surrounding an outer periphery of the first portion is defined as a second portion, and a portion surrounding an outer periphery of the second portion is defined as a third portion, a plating film is disposed on a surface of the second portion, and a ceramic protective film made of a ceramic material is disposed on a surface of the third portion.

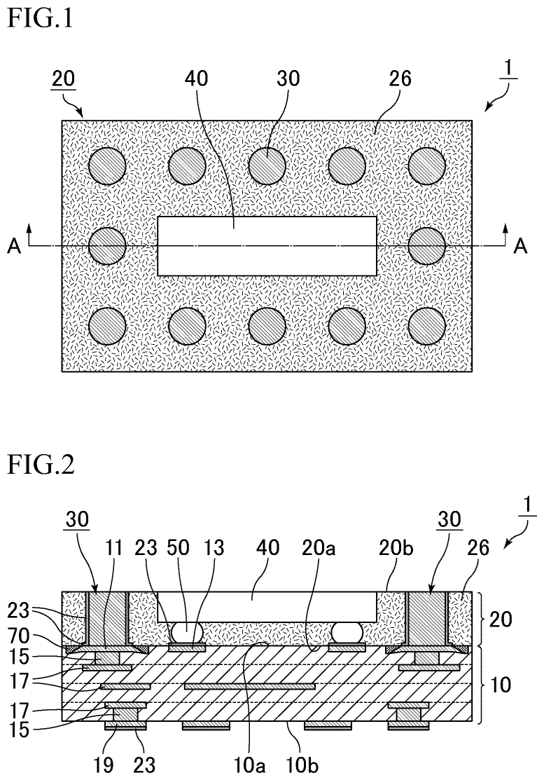

FIG. 1 is a schematic top view of an example of a circuit module of the present disclosure. FIG. 2 is a cross-sectional view taken along line A-A in FIG. 1.

As shown in FIG. 1 and FIG. 2, a circuit module 1 includes a substrate 10, a first resin layer 20, and connection terminals 30, and an electronic component 40 and the connection terminals 30 are exposed on the main surface of the first resin layer 20 opposite to the substrate 10.

As shown in FIG. 2, the substrate 10 has one main surface 10a and an other main surface 10b, and includes first electrodes 11 and second electrodes 13 on or in the one main surface 10a; via conductors 15 and wiring lines 17 therein; and third electrodes 19 on the other main surface 10b.

The first resin layer 20 is disposed adjacent to the main surface 10a of the substrate 10, and the one main surface 10a of the substrate 10 is covered with a sealing resin 26.

The first resin layer 20 has a first main surface 20a adjacent to the substrate 10 and a second main surface 20b opposite to the substrate 10.

The electronic component 40 is mounted on the one main surface 10a of the substrate 10.

The electronic component 40 is connected to the second electrodes 13 via solder portions 50.

The electronic component 40 can be said to be in the first resin layer 20.

As shown in FIG. 2, a plating film 23 may be formed on a surface of each second electrode 13.

The plating film 23 may also be formed on a surface of each third electrode 19 as shown in FIG. 2.

The connection terminals 30 are disposed adjacent to the one main surface 10a of the substrate 10.

One end of each connection terminal 30 is bonded to the corresponding first electrode 11, and the other end is exposed on the second main surface 20b of the first resin layer 20.

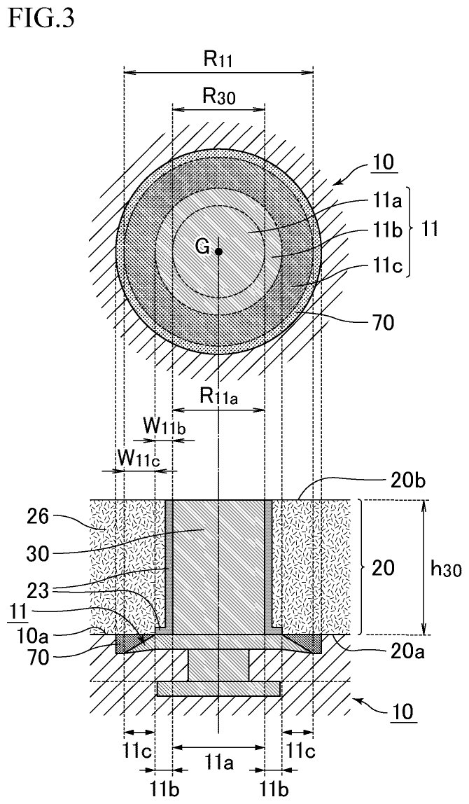

The connection terminal 30 extends in the thickness direction of the substrate 10 (the vertical direction in the view), and its height (height indicated by the double-headed arrow h₃₀ in FIG. 3) is equal to the thickness of the first resin layer 20 such that the connection terminal 30 passes from the first main surface 20a to the second main surface 20b of the first resin layer 20.

The surface of the connection terminal 30 exposed on the second main surface 20b of the first resin layer 20 is not covered with a plating film, but may be covered with a plating film. The plating film may be integrated with or separated from the plating film on the lateral surface of the connection terminal 30.

FIG. 3 is a diagram illustrating the correspondence between a partially enlarged view of FIG. 2 and a schematic view of a bonding interface between a connection terminal and a first electrode, when viewed from a connection terminal side, in the enlarged view.

The lower view in FIG. 3 is a partially enlarged view of FIG. 2, and the upper view in FIG. 3 is a schematic view of a bonding interface between a connection terminal and a first electrode, when viewed from a connection terminal side, in the enlarged view.

As shown in the lower view in FIG. 3, the direction in which the first electrode 11 extends (the lateral direction in the view) is perpendicular to the direction in which the connection terminal 30 extends (the vertical direction in the view).

As shown in FIG. 3, in the first electrode 11, three portions, namely, a first portion, a second portion, and a third portion, are defined.

The first portion defines a portion of the first electrode 11 bonded to the connection terminal 30 (the portion indicated by the reference numeral 11a and the double-headed arrow 11a in FIG. 3).

The second portion defines a portion surrounding the outer periphery of a first portion 11a (the portion indicated by the reference numeral 11b and the double-headed arrow 11b in FIG. 3).

The third portion defines a portion surrounding the outer periphery of a second portion 11b (the portion indicated by the reference numeral 11c and the double-headed arrow 11c in FIG. 3).

A surface of the first portion 11a of the first electrode 11 is bonded to the connection terminal 30. The first portion 11a of the first electrode 11 is flush with the one main surface 10a of the substrate 10.

The plating film 23 is disposed on a surface of the second portion 11b of the first electrode 11. The second portion 11b of the first electrode 11 is flush with the one main surface 10a of the substrate 10.

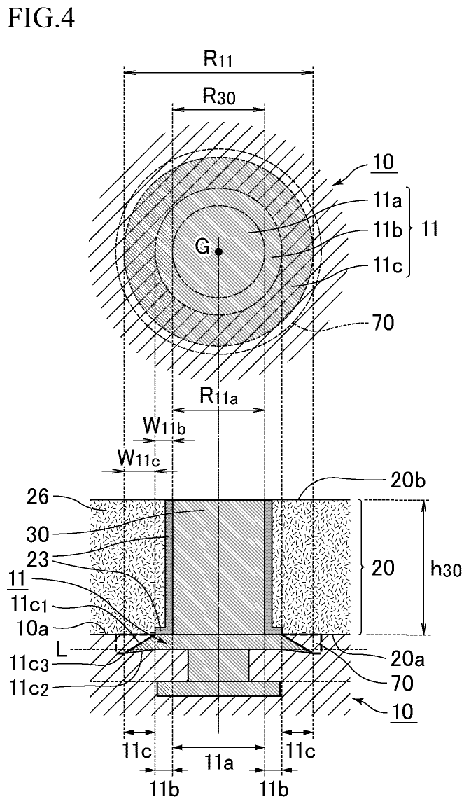

A ceramic protective film 70 made of a ceramic material is disposed on a surface of a third portion 11c of the first electrode 11. The third portion 11c of the first electrode 11 can be said to be embedded below the ceramic protective film 70. As may be seen in FIG. 4, the third portion 11c may be bent or tapered away from the connection terminal, i.e., thickness of the ceramic protective film 70 increases away from the second portion 11b to cover the third portion 11c.

As shown in FIG. 3, when the plating film 23 is disposed on the surface of the second portion 11b of the first electrode 11 and the ceramic protective film 70 is disposed on the surface of the third portion 11c of the first electrode 11, the thermal expansion of the first portion 11a is less likely to be transmitted directly to the substrate, thereby improving the thermal cycle characteristics. Furthermore, when the ceramic protective film 70 is disposed on the third portion 11c outside the plating film 23, the mechanical strength of the first electrode 11 increases, thereby contributing to improvement of thermal cycle characteristics.

Herein, unless otherwise specified, the surface of the first electrode refers to the surface of the first electrode adjacent to the connection terminal. In other words, the surface of the first electrode adjacent to the connection terminal is the surface that can be seen when the first electrode is viewed in the thickness direction from the connection terminal side.

As shown in the upper view of FIG. 3, when the first electrode 11 is viewed in the thickness direction, the first portion 11a has a circular shape having a diameter R₁₁ₐ, the second portion 11b has an annular shape surrounding the outer periphery of the first portion 11a and having a width W_{11b}, and the third portion 11c has an annular shape surrounding the outer periphery of the second portion 11b and having a width W_{11c}.

The diameter R₁₁ₐ of the first portion 11ₐ is equal to the diameter R₃₀ of the connection terminal 30.

The ceramic protective film 70 is also disposed to surround the outer periphery of the third portion 11c of the first electrode 11.

For example, in the upper view in FIG. 3, the ceramic protective film 70 covers the outer periphery of the third portion 11c of the first electrode 11.

### Substrate

The substrate has one main surface and the other main surface.

The substrate is a laminate of insulating layers provided with conductor patterns that constitute a circuit, for example.

Examples of the conductor patterns include electrodes exposed on the one or the other main surface of the substrate, and wiring lines and via conductors in the substrate.

The substrate includes a first electrode on or in the one main surface.

The first electrode is bonded to a connection terminal.

The substrate may include a second electrode on or in the one main surface.

The second electrode is, for example, connected to an electronic component.

The substrate may include a third electrode on the other main surface.

The third electrode is, for example, connected to an electronic component.

Examples of the electronic component include a multilayer capacitor, a multilayer inductor, a filter, and an IC.

The ceramic material constituting the insulating layers may be a low temperature co-fired ceramic (LTCC) material.

The low temperature co-fired ceramic material is a ceramic material that can be fired at a temperature of 1000° C. or lower and that can be co-sintered with a low-resistive material such as Au, Ag, or Cu. Specific examples of the low temperature co-fired ceramic material include glass composite low temperature co-fired ceramic materials obtained by mixing a ceramic powder of alumina, zirconia, magnesia, forsterite, or the like with borosilicate glass; crystallized glass low temperature co-fired ceramic materials containing ZnO—MgO—Al₂O₃—SiO₂ crystallized glass; and non-glass low temperature co-fired ceramic materials containing BaO—Al₂O₃—SiO₂ ceramic powder, Al₂O₃—CaO—SiO₂—MgO—B₂O₃ ceramic powder, or the like.

It suffices that the conductor patterns are made of any conductive material that can be co-fired with a low-temperature co-fired ceramic material, and examples include Cu, Ag, Au, and alloys thereof.

### First Electrode

The first electrode is disposed on or in the one main surface of the substrate.

Herein, in the first electrode when viewed in the thickness direction, three portions, namely, a first portion, a second portion, and a third portion, are defined.

The first portion is bonded to a connection terminal.

The second portion surrounds the outer periphery of the first portion.

The third portion surrounds the outer periphery of the second portion.

The surface of the first portion of the first electrode is bonded to the connection terminal.

A plating film is disposed on the surface of the second portion of the first electrode.

A ceramic protective film made of a ceramic material is disposed on the surface of the third portion of the first electrode.

The first portion, the second portion, and the third portion of the first electrode can be defined by the following procedure.

First, a portion of the first electrode bonded to the connection terminal is identified. The portion of the first electrode bonded to the connection terminal when viewed in the thickness direction is defined as the first portion.

Next, a portion of the surface of the first electrode with a plating film surrounding the first portion is identified. A portion corresponding to the portion of the first electrode with a plating film surrounding the first portion is defined as the second portion.

Finally, a portion of the surface of the first electrode with a ceramic protective film surrounding the second portion is identified. A portion corresponding to the portion of the first electrode with a ceramic protective film surrounding the second portion is defined as the third portion.

The surface of the first electrode refers to the surface of the first electrode adjacent to the connection terminal.

The surface of the first electrode opposite to the connection terminal is connected to a via conductor in the substrate.

The first portion, when viewed in the thickness direction, may have any shape, and examples include a circle and a polygon.

The first portion, when viewed in the thickness direction, may have any area, and the area may be 25000 μm² or more and 50000 μm² or less.

The first portion of the first electrode may have a thickness of 5 μm or more and 20 μm or less.

The second portion, when viewed in the thickness direction, may have an annular shape surrounding the outer periphery of the first portion.

The second portion, when viewed in the thickness direction, may have a width of 10 μm or more and 30 μm or less.

For example, when the second portion, when viewed in the thickness direction, has a circular annular shape, the width of the second portion can be calculated by {[(outer diameter of second portion)−(inner diameter of second portion)]/2}.

The second portion, when viewed in the thickness direction, may have any area, and the area may be 2900 μm² or more and 21600 μm² or less.

The second portion may have a thickness of 5 μm or more and 20 μm or less.

Also, the thickness of the second portion may be the same as the thickness of the first portion.

The third portion, when viewed in the thickness direction, may have an annular shape surrounding the outer periphery of the second portion.

The third portion, when viewed in the thickness direction, may have a width of 20 μm or more and 50 μm or less.

For example, when the third portion, when viewed in the thickness direction, has a circular annular shape, the width of the third portion can be calculated by {[(outer diameter of third portion)−(inner diameter of third portion)]/2}.

The thickness of the third portion of the first electrode may gradually decrease from the center (the second portion) outward.

In other words, the surface of the third portion of the first electrode may be inclined outward.

When viewed in the thickness direction, the width of the third portion may be greater than the width of the second portion.

When the width of the third portion is greater than the width of the second portion, the contribution of the thermal expansion of the ceramic protective film on the surface of the third portion is higher than the contribution of the thermal expansion of the plating film on the surface of the second portion, and the ceramic protective film easily reduces the thermal expansion of the second portion.

When viewed in the thickness direction, the total area of the third portion may be greater than the sum of the area of the first portion and the area of the second portion.

The area of the third portion means the area obtained by projecting the third portion in the thickness direction, that is, the maximum projected area.

When the area of the third portion is greater than the sum of the area of the first portion and the area of the second portion, the ceramic protective film easily reduces thermal expansion of the first portion and the second portion.

### Connection Terminal

A connection terminal is disposed adjacent to the one main surface of the substrate.

One end of the connection terminal adjacent to the one main surface of the substrate is bonded to part of the first electrode.

The connection terminal extends along the thickness direction of the substrate, and the other end of the connection terminal is exposed on the second main surface of the first resin layer.

The height of the connection terminal can be adjusted appropriately in accordance with the height of an electronic component mounted on the one main surface of the substrate.

The height of the connection terminal can be, for example, 30 μm or more and 150 μm or less.

It suffices that the connection terminal has a columnar shape. For example, the connection terminal may have a cylindrical shape or a polygonal shape.

A columnar connection terminal is also called a metal post.

The connection terminal may have a tapered shape.

Examples of a material constituting the connection terminal include Cu, Ag, Au, and alloys thereof.

The connection terminal, when it has a cylindrical shape, may have a diameter of 150 μm or more and 250 μm or less, e.g., 180 μm or more and 250 μm or less.

### Plating Film

Examples of a material constituting the plating film include Cu, Ag, Au, Ni, Sn, and Pd.

The plating film disposed on the surface of the second portion of the first electrode may be, but not limited to, 5 μm or more and 10 μm or less.

### Ceramic Protective Film

An example of a material constituting the ceramic protective film is a low temperature co-fired ceramic (LTCC) material.

The ceramic protective film may cover the outer periphery of the third portion.

The low temperature co-fired ceramic constituting the ceramic protective film may be the same as or different from the low temperature co-fired ceramic constituting the substrate.

When the coefficient of thermal expansion of the connection terminal is defined as μ₁, the coefficient of thermal expansion of the interfacial plating film is defined as μ₂, and the coefficient of thermal expansion of the ceramic protective film is defined as μ₃, they may satisfy the relationship μ₁>μ₂>μ₃. When the connection terminal, plating film, and ceramic protective film disposed on the surface of the first electrode are arranged from the inside to the outside in the order of large to small coefficients of thermal expansion, the thermal expansion of the connection terminal is less likely to be transmitted to the outer substrate. In other words, the arrangement of materials from the inside (terminal) to the outside (ceramic protective film) creates a “gradient” or “buffer” that prevents the direct transmission of thermal stress to the substrate.

The coefficient of thermal expansion μ₁ of the connection terminal, the coefficient of thermal expansion μ₂ of the plating film, and the coefficient of thermal expansion μ₃ of the ceramic protective film can each be measured by thermomechanical analysis.

The coefficient of thermal expansion μ₁ of the connection terminal may be 15×10⁻⁶ [K⁻¹] or more and 17×10⁻⁶ [K⁻¹] or less.

The coefficient of thermal expansion μ₂ of the plating film may be 13×10⁻⁶ [K⁻¹] or more and 15×10⁻⁶ [K⁻¹] or less.

The coefficient of thermal expansion μ₃ of the ceramic protective film may be 3×10⁻⁶ [K⁻¹] or more and 12×10⁻⁶ [K⁻¹] or less.

When the low temperature co-fired ceramic constituting the ceramic protective film and the low temperature co-fired ceramic constituting the substrate have the same material composition, the ceramic protective film may not be identified on the surface of the third portion of the first electrode. An example of this case is described with reference to FIG. 4.

FIG. 4 is a diagram illustrating the correspondence between an enlarged view of a bonding portion between a connection terminal and a first electrode in another example of the circuit module of the present disclosure and a schematic view, when viewed from the connection terminal side, of the bonding interface between the connection terminal and the first electrode in the enlarged view.

The lower view in FIG. 4 is a partially enlarged view of the bonding portion between the connection terminal and the first electrode, and the upper view in FIG. 4 is a schematic view, when viewed from the connection terminal side, of the bonding interface between the connection terminal and the first electrode in the enlarged view.

In the circuit module shown in FIG. 4, similarly to the circuit module shown in FIG. 3, three portions, namely, a first portion, a second portion, and a third portion, are defined in the first electrode.

The first portion 11a is bonded to the connection terminal 30.

The second portion 11b surrounds the outer periphery of the first portion 11a.

The third portion 11c surrounds the outer periphery of the second portion 11b.

The first portion 11a of the first electrode 11 is bonded to the connection terminal 30.

The plating film 23 is disposed on a surface of the second portion 11b of the first electrode 11.

The surface of the second portion 11b of the first electrode 11 is not in contact with the connection terminal 30 and the sealing resin 26 constituting the first resin layer 20.

The ceramic protective film 70 made of a ceramic material is disposed d on a surface of the third portion 11c of the first electrode 11.

When the ceramic material constituting the ceramic protective film 70 disposed on the surface of the third portion 11c of the first electrode 11 and the ceramic material constituting the substrate 10 have the same composition, the ceramic protective film cannot be distinguished from the substrate 10 in the cross section shown in the lower view in FIG. 4.

In FIG. 4, a region where the ceramic protective film is presumed to be formed is indicated by a dashed line and is denoted by reference numeral 70.

The third portion 11c surrounds the outer periphery of the second portion 11b and constitutes the outermost portion of the first electrode 11. Thus, once the second portion 11b is determined, the entire region outside the second portion 11b is determined as the third portion 11c.

Thus, when the first electrode 11 is viewed in the thickness direction, the first portion 11a has a circular shape having a diameter R₁₁ₐ, the second portion 11b has an annular shape surrounding the outer periphery of the first portion 11a and having a width W_{11b}, and the third portion 11c has an annular shape surrounding the outer periphery of the second portion 11b and having a width W_{11c}.

The thickness of the third portion 11c of the first electrode 11 gradually decreases outward (decreases away from the first portion).

In other words, the thickness of the ceramic material between the surface 11c₁ of the third portion 11c of the first electrode 11 and the first resin layer 20 decreases towards the second portion 11b and increases away from the second portion 11b.

In the first portion 11a and the second portion 11b, the surface of the first electrode 11 adjacent to the connection terminal 30 and the surface of the first electrode 11 opposite to the connection terminal 30 are parallel, whereas in the third portion 11c, the surface 11c₁ of the first electrode 11 adjacent to the connection terminal 30 and a surface 11c₂ of the first electrode 11 opposite to the connection terminal 30 are not parallel.

Each of the cross sections of the third portion 11c of the first electrode 11 in FIG. 4 has a shape defined by a side extending from the corresponding outer edge of the second portion 11b of the first electrode 11 on the surface adjacent to the connection terminal 30 toward the corresponding widthwise end 11c₃ of the first electrode 11 (i.e., a side corresponding to the surface 11c₁) and a side extending from the corresponding outer edge of the second portion 11b of the first electrode 11 on the surface opposite to the connection terminal 30 toward the widthwise end 11c₃ of the first electrode 11 (i.e., a side corresponding to the surface 11c₂).

The outer edges of the third portion 11c of the first electrode 11, i.e., the widthwise ends 11c₃ of the first electrode 11 in the cross-sectional view, may be on an extension plane L extending from the surface of the first portion 11a and the second portion 11b of the first electrode 11 opposite to the connection terminal 30, or may be located away from the connection terminal 30 relative to the extension plane L (that is, may be located on the lower part of the view).

The widthwise ends 11c₃ of the first electrode 11 shown in FIG. 4 are located away from the connection terminal 30 relative to the extension plane L (that is, are located on the lower part of the view).

In this case, it can be said that the third portion 11c of the first electrode 11 is slightly bent away from the connection terminal 30. The bending points correspond to the boundary between the second portion 11b and the third portion 11c.

### First Resin Layer

The first resin layer may be disposed adjacent to the one main surface of the substrate.

The first resin layer has a first main surface adjacent to the substrate and a second main surface opposite to the substrate.

When the first resin layer is present, the connection terminals are disposed in the first resin layer.

The sealing resin constituting the first resin layer may be either a thermosetting resin or a thermoplastic resin. Examples of the thermosetting resin include a phenol resin, an epoxy resin, a polyester resin, a silicone resin, and a polyimide resin. Examples of the thermoplastic resin include a thermoplastic liquid crystal polymer (LCP), a thermoplastic polyimide resin, a polyether ether ketone resin (PEEK), and a polyphenylene sulfide resin (PPS).

The sealing resin constituting the first resin layer may contain additives such as a filler.

Examples of the filler include glass, silica, aluminum oxide, aluminum nitride, and boron nitride.

A second resin layer may be disposed on the other main surface of the substrate.

An electronic component may be disposed in the second resin layer.

When an electronic component is disposed in the second resin layer, the electronic component may be connected via solder to third electrodes on the other main surface of the substrate.

In this case, the electronic component can be said to be mounted on the other main surface of the substrate.

The types of sealing resin and filler constituting the second resin layer may be the same as or different from those constituting the first resin layer.

### Shielding Film

A shielding film may be disposed on the surface of the second resin layer opposite to the substrate (top surface), a side surface of the second resin layer, and a side surface of the substrate.

The shielding film can be formed by, for example, sputtering. Instead of sputtering, the shielding film can be formed by conventional methods such as application of a conductive resin, plating, and vapor deposition.

In this case, a ground electrode may be exposed on a side surface of the substrate and is connected to the shielding film.

The shielding film may extend to a side surface of the first resin layer.

The circuit module may include a plurality of connection terminals.

### Method of Producing Circuit Module

The following describes an example of a method of producing a circuit module of the present disclosure with reference to the figures.

The order of the steps, the number of layers laminated, and the configuration of each sheet described below are not limited to the contents described in the figures.

The steps described below are intended for producing a separate circuit module. Alternatively, an assembly of circuit modules produced may be divided into separate modules.

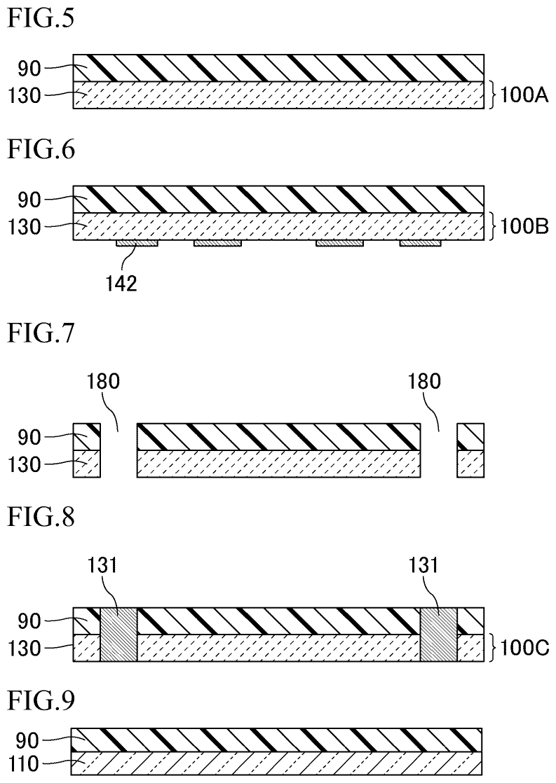

FIG. 5 is a schematic cross-sectional view of an example of a constraining-layer sheet used to produce a circuit module.

First, as shown in FIG. 5, a laminate of a constraining-layer sheet 130 and a carrier film 90 is prepared.

The constraining-layer sheet 130, from which the carrier film 90 has been removed, is also referred to as a lamination sheet 100A.

A laminate of a constraining-layer sheet and a carrier film as shown in FIG. 5 can be prepared by applying a slurry prepared by mixing a hard-to-sinter ceramic material as a raw material for a constraining-layer sheet, an organic binder, and a plasticizer in appropriate amounts to a surface of a carrier film to form a sheet thereon.

An example of the hard-to-sinter ceramic material is Al₂O₃ powder.

FIG. 6 is a schematic cross-sectional view of printing a conductive paste on a surface of the constraining-layer sheet shown in FIG. 5.

As shown in FIG. 6, a conductive paste 142 is printed on a surface of the constraining-layer sheet 130 shown in FIG. 5.

Thereby, a lamination sheet 100B is obtained in which the conductive paste 142 is printed on the surface of the constraining-layer sheet 130.

The conductive paste can be obtained, for example, by dispersing a conductive material in an organic binder.

An example of the conductive material is copper powder.

The conductive paste is printed on the surface of the constraining-layer sheet by a known technique such as screen printing.

FIG. 7 is a schematic cross-sectional view of forming through holes in the constraining-layer sheet shown in FIG. 5.

As shown in FIG. 7, through holes 180 are formed in the constraining-layer sheet 130 shown in FIG. 5.

The through holes may be formed by any technique such as laser irradiation or drilling.

FIG. 8 is a schematic cross-sectional view of filling the through holes of the constraining-layer sheet shown in FIG. 7 with a conductive paste.

Subsequently, as shown in FIG. 8, the through holes 180 of the constraining-layer sheet 130 shown in FIG. 7 are filled with a conductive paste.

Thereby, a lamination sheet 100C is obtained in which a conductive paste 131 fills the through holes 180 that penetrate the constraining-layer sheet 130 in its thickness direction.

The conductive paste 131 filling the through holes 180 is converted into connection terminals by sintering.

The through holes are filled with the conductive paste by a known technique such as screen printing.

FIG. 9 is a schematic cross-sectional view of an example of a ceramic green sheet used to produce a circuit module.

As shown in FIG. 9, a laminate of a carrier film 90 and a ceramic green sheet 110 is prepared.

A laminate of a ceramic green sheet and a carrier film as shown in FIG. 9 can be prepared by applying a slurry prepared by mixing a low temperature co-fired ceramic material, an organic binder, and a plasticizer in appropriate amounts to a surface of a carrier film to form a sheet thereon.

FIG. 10 is a schematic cross-sectional view of printing a conductive paste on a surface of the ceramic green sheet shown in FIG. 9.

Subsequently, as shown in FIG. 10, a conductive paste 142 is printed on a surface of the ceramic green sheet 110 shown in FIG. 9.

Thereby, a lamination sheet 100D can be obtained in which the conductive paste 142 is printed on the surface of the ceramic green sheet 110.

In FIG. 15, which is described later, two types of lamination sheets 100D that differ in the position of the printed conductive paste 142 are used.

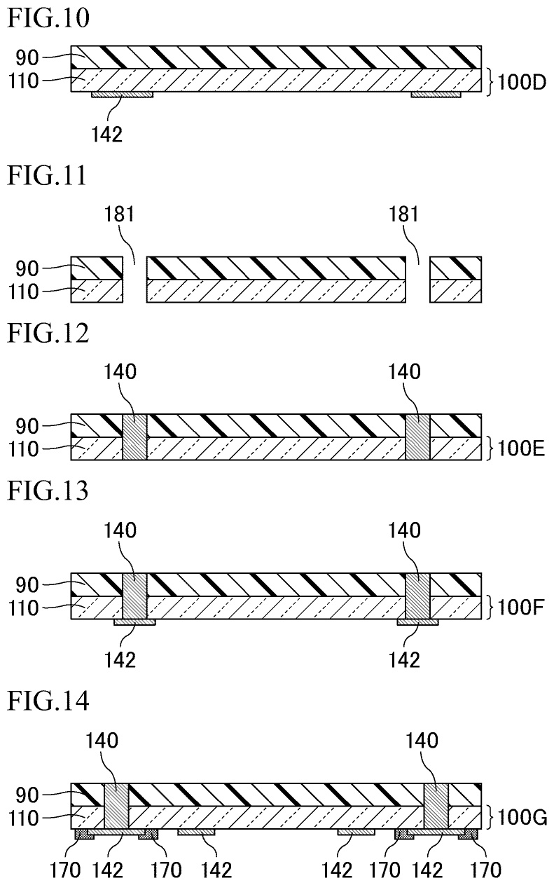

FIG. 11 is a schematic cross-sectional view of forming through holes in the ceramic green sheet shown in FIG. 9.

As shown in FIG. 11, through holes 181 are formed in the ceramic green sheet 110 shown in FIG. 9.

The through holes may be formed as in the step shown in FIG. 7.

FIG. 12 is a schematic cross-sectional view of filling the through holes of the ceramic green sheet shown in FIG. 11 with a conductive paste.

Subsequently, as shown in FIG. 12, the through holes 181 are filled with a conductive paste.

Thereby, a lamination sheet 100E is obtained in which a conductive paste 140 fills the through holes 181 that penetrate the ceramic green sheet 110 in its thickness direction.

FIG. 13 is a schematic cross-sectional view of printing a conductive paste on a surface of the ceramic green sheet shown in FIG. 12.

Subsequently, as shown in FIG. 13, a conductive paste 142 is printed on the surface of the ceramic green sheet 110 shown in FIG. 12.

Thereby, a lamination sheet 100F is obtained in which the conductive paste 140 fills the through holes 181 that penetrate the ceramic green sheet 110 in its thickness direction and the conductive paste 142 is printed on the surface of the ceramic green sheet 110.

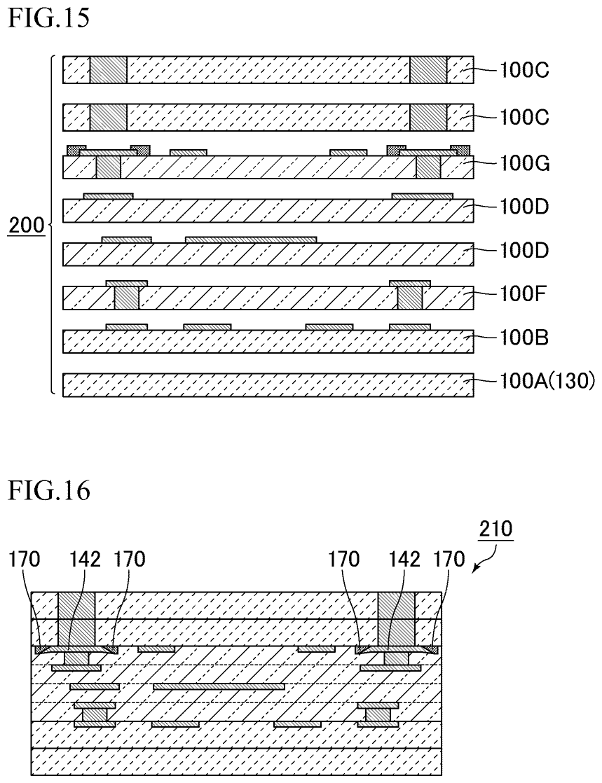

FIG. 14 is a schematic cross-sectional view of printing a conductive paste and a ceramic protective film paste on the surface of the ceramic green sheet shown in FIG. 12.

Subsequently, as shown in FIG. 14, a conductive paste 142 is printed on a surface of the ceramic green sheet 110 shown in FIG. 12, and a ceramic protective film paste 170 is printed on the surface of the ceramic green sheet 110 so as to partially overlap a surface of the printed conductive paste 142.

Here, the ceramic protective film paste 170 surrounds the outer edge of the conductive paste 142, which is converted into a first electrode.

Thereby, a lamination sheet 100G is obtained in which the conductive paste 142, which is converted into a first electrode, and the conductive paste 142, which is converted into a second electrode, are printed on the surface of the ceramic green sheet 110, and the ceramic protective film paste 170 is printed so as to surround the outer edge of the conductive paste 142, which is converted into a first electrode.

Here, a portion of the conductive paste 142 printed on the surface of the ceramic green sheet 110 in FIG. 14 overlaps the conductive paste 142 printed on the surface of the ceramic green sheet 110 in FIG. 13.

FIG. 15 is a schematic view of an example of stacking prepared lamination sheets.

As shown in FIG. 15, the lamination sheets 100A to 100G prepared in the above-described steps are stacked in a predetermined order.

In FIG. 15, the lamination sheet 100C, the lamination sheet 100C, the lamination sheet 100G, the lamination sheet 100D, the lamination sheet 100D, the lamination sheet 100F, the lamination sheet 100B, and the lamination sheet 100A are sequentially stacked from top to bottom to form a stack 200.

FIG. 16 is a schematic view of an example of compression bonding of a stack.

As shown in FIG. 16, the stack 200 is compression-bonded to obtain a compression-bonded body 210.

The ceramic protective film paste 170 is printed to cover the outer edge of the conductive paste 142, which is converted into a first electrode. Thus, upon compression bonding, a portion of the conductive paste 142, which is converted into a first electrode, that overlaps the ceramic protective film paste 170 bends toward the inside of the substrate (a lower part of the view) and deforms such that the thickness of the portion decreases outward.

As a result, the shape of the conductive paste 142 changes to the shape of the first electrode 11 shown in FIG. 3.

The pressure and temperature during compression-bonding the stack may be set freely according to the design.

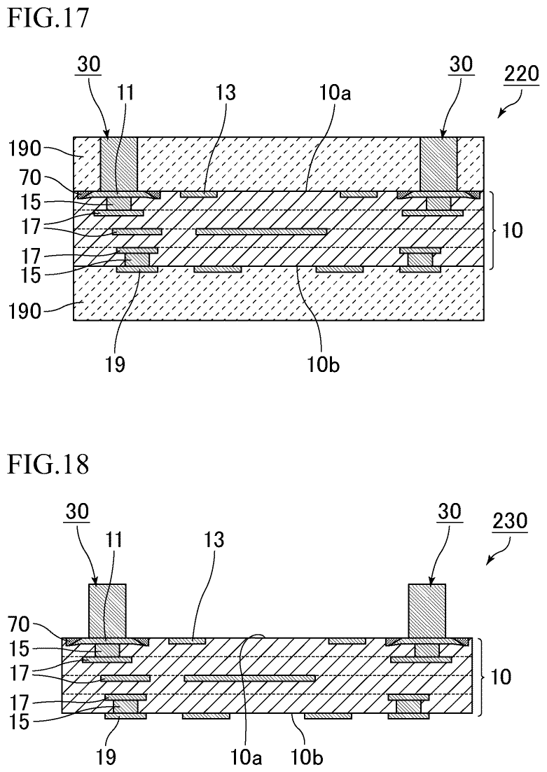

FIG. 17 is a schematic view of an example of firing a compression-bonded body.

As shown in FIG. 17, the compression-bonded body 210 is fired so that the conductive paste fills the through holes and the printed conductive paste are sintered and the ceramic green sheets are sintered. Thereby, a fired body 220 is obtained.

Here, the ceramic green sheets are sintered to form the substrate 10, and the conductive paste filling the through holes of the constraining-layer sheets is sintered to form the connection terminals 30.

Also, the conductive paste filling the through holes of the ceramic green sheets or printed on the ceramic green sheets is sintered to form the first electrodes 11, the second electrodes 13, the via conductors 15, the wiring lines 17, and the third electrodes 19.

Also, the ceramic green sheets 110 and the ceramic protective film paste 170 are sintered to form the substrate 10 and the ceramic protective film 70, respectively.

The surface of each first electrode 11 is partially bonded to the corresponding connection terminal 30. A portion corresponding to the surface of each first electrode 11 partially bonded to the corresponding connection terminal 30 is the first portion.

The surface of the first electrode 11 is partially provided with the ceramic protective film 70. A portion corresponding to the surface of the first electrode 11 partially provided with the ceramic protective film 70 is the third portion.

Here, when the ceramic material constituting the ceramic green sheets 110 and the ceramic material constituting the ceramic protective film paste 170 have the same material composition, the ceramic protective film may not be distinguished from the ceramic material constituting the substrate in the fired body 220.

As shown in FIGS. 15 and 16, in the compression-bonded body 210 where the constraining-layer sheet 130 is laminated on the surface of the ceramic protective film paste 170, a part of the hard-to-sinter ceramic components constituting the constraining-layer sheet 130 may diffuse toward the ceramic protective film paste 170 during firing. In such a case, a region outside the second portion of the first electrode may be subjected to elemental mapping or the like to determine an area where the content of elements constituting the hard-to-sinter ceramic is high. Thereby, a portion where the ceramic protective film is formed (a region where the ceramic protective film 70 is formed as shown in FIG. 4) may be indirectly determined. In other words, by identifying high concentrations of hard-to-sinter elements may serve as a diagnostic tool to verify the boundary of the third portion 11c.

The firing may be performed using a firing furnace such as a batch furnace or a belt furnace.

The firing temperature is may be, but not limited to, 800° C. or higher and 1000° C. or lower.

FIG. 18 is a schematic view of an example of removing a constraining layer.

Subsequently, as shown in FIG. 18, a constraining layer 190 (a residue of the constraining-layer sheets) is removed by cleaning.

Removing the constraining layer exposes the connection terminals 30 on the one main surface 10a of the substrate 10, and an object to be cleaned 230 is obtained.

The constraining layer may be removed by any known technique such as sandblasting.

Removing the constraining layer 190 exposes a portion of the surface of the first electrode 11 other than the first portion and the third portion, which corresponds to the second portion.

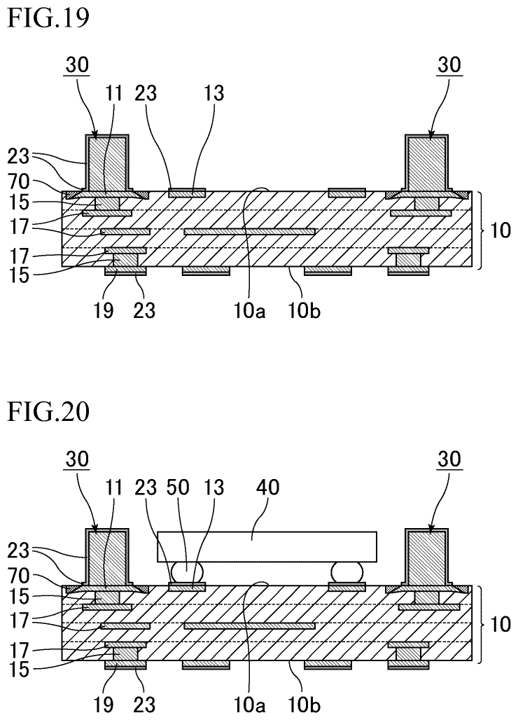

FIG. 19 is a schematic view of an example of forming a plating film.

Subsequently, as shown in FIG. 19, a surface of the substrate 10 is subjected to plating to form a plating film.

Thereby, the plating film 23 is formed on the lateral surface and the upper surface of each connection terminal 30, part of the surface of each first electrode 11, the surface of each second electrode 13, and the surface of each third electrode 19.

A portion corresponding to the surface of the first electrode 11 on which the plating film 23 is formed is the second portion other than the first portion and the third portion.

Since the surface of the first portion of the first electrode 11 is bonded to the corresponding connection terminal 30, and the surface of the third portion of the first electrode 11 is provided with the ceramic protective film 70, no plating film 23 is formed on these surfaces.

FIG. 20 is a schematic view of an example of mounting an electronic component on one main surface of a substrate.

Subsequently, as shown in FIG. 20, an electronic component is mounted on the one main surface 10a of the substrate 10 using the second electrodes 13.

The solder portions 50 are disposed between the second electrodes 13 and the electronic component 40.

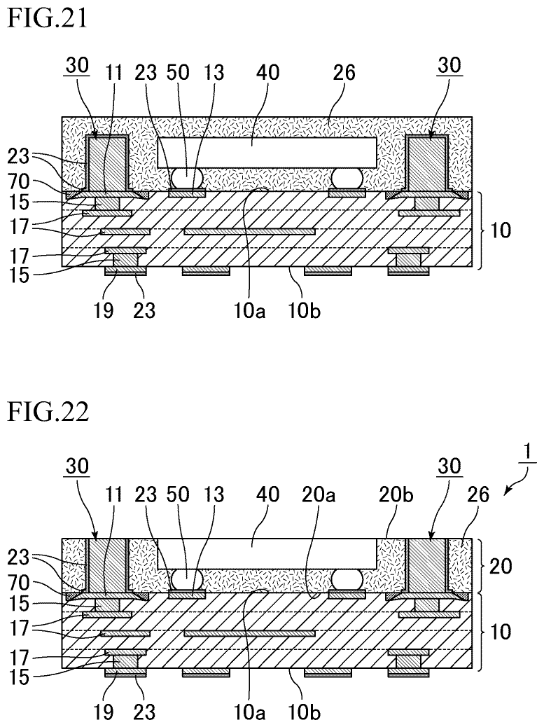

FIG. 21 is a schematic cross-sectional view of an example of sealing the electronic component.

Subsequently, as shown in FIG. 21, the sealing resin 26 is provided on the one main surface 10a of the substrate.

Thereby, the electronic component 40 is sealed with the sealing resin 26.

FIG. 22 is a schematic cross-sectional view of an example of grinding a sealing resin surface.

Subsequently, as shown in FIG. 22, the surface of the sealing resin 26 is ground to expose the connection terminals 30.

In FIG. 22, the top surface of the electronic component 40 is also exposed, but the top surface of the electronic component 40 does not have to be exposed.

Through the above-described steps, the circuit module 1 described with reference to FIG. 2 is obtained.

In the above, a method is described in which a ceramic green sheet or a constraining-layer sheet is formed on a carrier film and removed from the carrier film, and the resulting sheets are stacked together. Alternatively, a method may be employed in which, for example, a ceramic green sheet is formed on a surface of a carrier film, and a constraining-layer sheet is formed on the surface of the ceramic green sheet.

The constraining-layer sheet may be formed on the surface of the ceramic green sheet by a method similar to the method of forming a constraining-layer sheet on a surface of a carrier film.

In addition to the above-described steps, a plating film may be formed on the surfaces of the connection terminals exposed on the second main surface of the first resin layer.

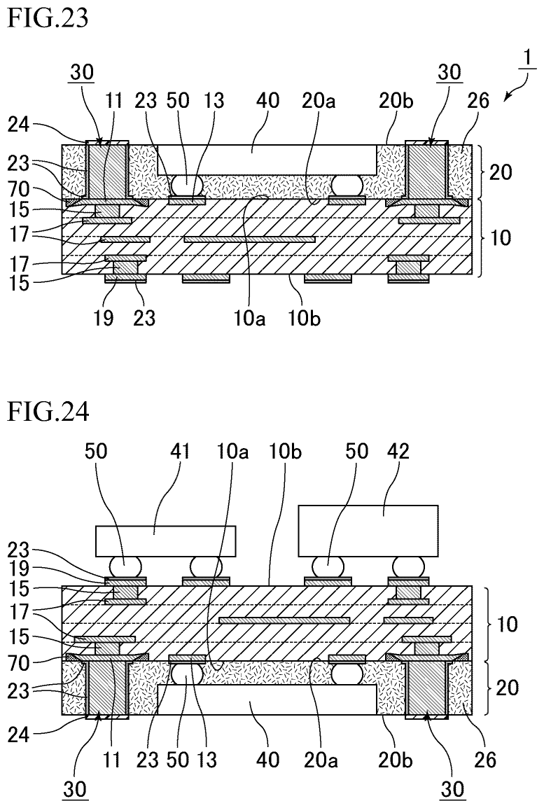

FIG. 23 is a schematic cross-sectional view of forming a plating film on a surface of each of connection terminals.

As shown in FIG. 23, a plating film 24 may be formed on the surface of each connection terminal 30.

The plating film 24 can be formed, for example, by subjecting the circuit module 1 shown in FIG. 23 to plating.

The plating film 24 may be formed of, for example, Ni and/or Sn.

Such an additional step can form a plating film on the surfaces of the connection terminals exposed on the second main surface of the first resin layer.

In addition to the above-described steps, an electronic component may be mounted on the other main surface of the substrate and sealed with a sealing resin to form the second resin layer.

FIG. 24 is a schematic cross-sectional view of mounting electronic components on the other main surface of the substrate.

Subsequently, as shown in FIG. 24, an electronic component 41 and an electronic component 42 are mounted on the other main surface 10b of the substrate 10.

The electronic component 41 and the electronic component 42 are each connected to the corresponding third electrodes 19 disposed on the other main surface 10b of the substrate 10 via the corresponding solder portions 50.

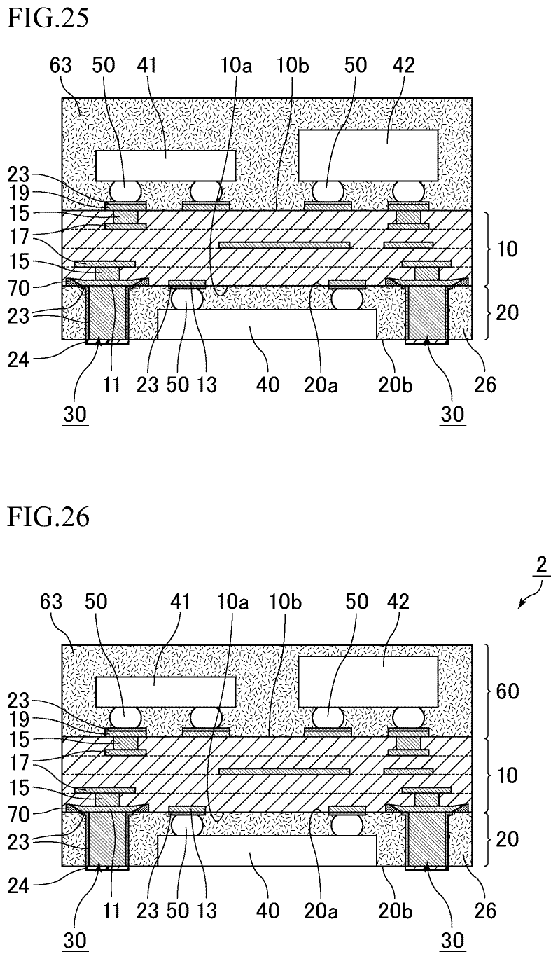

FIG. 25 is a schematic cross-sectional view of an example of sealing the electronic components.

Subsequently, as shown in FIG. 25, a sealing resin 63 is provided on the other main surface 10b of the substrate 10.

Thereby, the electronic component 41 and the electronic component 42 are sealed with the sealing resin 63.

FIG. 26 is a schematic cross-sectional view of an example of grinding a sealing resin surface.

Subsequently, as shown in FIG. 26, the surface of the sealing resin 63 is ground to adjust the shape of the second resin layer 60.

Through the above-described steps, the electronic component 41 and the electronic component 42 are mounted on the other main surface 10b of the substrate 10 and sealed with the sealing resin 63. Thereby, the circuit module 2 including the second resin layer 60 is obtained.

The present description discloses the following.

Disclosure (1) relates to a circuit module including: a substrate having one main surface and an other main surface; and a connection terminal disposed adjacent to the one main surface of the substrate, wherein the substrate includes a first electrode on or in the one main surface, and one end of the connection terminal adjacent to the one main surface of the substrate is bonded to the first electrode, and wherein in the first electrode when viewed in a thickness direction, a portion of the first electrode bonded to the connection terminal is defined as a first portion, a portion surrounding an outer periphery of the first portion is defined as a second portion, and a portion surrounding an outer periphery of the second portion is defined as a third portion, a plating film is disposed on a surface of the second portion, and a ceramic protective film made of a ceramic material is disposed on a surface of the third portion.

Disclosure (2) relates to the circuit module according to Disclosure (1), wherein the circuit module satisfies the relationship μ₁>μ₂>μ₃ where μ₁ is a coefficient of thermal expansion of the connection terminal, μ₂ is a coefficient of thermal expansion of the plating film, and μ₃ is a coefficient of thermal expansion of the ceramic protective film.

Disclosure (3) relates to the circuit module according to Disclosure (1) or (2), wherein when viewed in the thickness direction, a width of the third portion is greater than a width of the second portion.

Disclosure (4) relates to the circuit module according to any combination of Disclosure (1) to Disclosure (3), wherein when viewed in the thickness direction, an area of the third portion is larger than a sum of an area of the first portion and an area of the second portion.

Disclosure (5) relates to the circuit module according to any combination of Disclosure (1) to Disclosure (4), wherein the second portion of the first electrode is flush with the one main surface of the substrate, and the third portion of the first electrode is embedded below the ceramic protective film.

### REFERENCE SIGNS LIST

1, 2 circuit module
10 substrate
10a one main surface of substrate
10b other main surface of substrate
11 first electrode
11a first portion of first electrode
11b second portion of first electrode
11c third portion of first electrode
11c₁ surface of third portion adjacent to connection terminal
11c₂ surface of third portion opposite to connection terminal
11c₃ widthwise end of first electrode
13 second electrode
15 via conductor
17 wiring line
19 third electrode
20 first resin layer
20a first main surface of first resin layer
20b second main surface of first resin layer
23, 24 plating film
26 sealing resin
30 connection terminal
40, 41, 42 electronic component
50 solder portion
60 second resin layer
63 sealing resin
70 ceramic protective film
90 carrier film
100A, 100B, 100C, 100D, 100E, 100F, 100G lamination sheet
110 ceramic green sheet
130 constraining-layer sheet
131, 140 filled conductive paste
142 printed conductive paste
150 ceramic paste
170 ceramic protective film paste
180, 181 through hole
190 constraining layer
200 stack
210 compression-bonded body
220 fired body
230 object to be cleaned
G center of gravity of first electrode
h₃₀ height of connection terminal
L extension plane extending from surface of first portion and second portion of first electrode opposite to connection terminal
R₃₀ diameter of connecting terminal
R₁₁ₐ diameter of first portion
W_{11b} width of second portion
W_{11c} width of third portion

1. A circuit module comprising:
a substrate having a first main surface and a second main surface;
a connection terminal disposed adjacent to the first main surface of the substrate;
wherein the substrate includes a first electrode on or in the first main surface, and
a first end of the connection terminal adjacent to the first main surface of the substrate is bonded to the first electrode, and
wherein, when viewed in a thickness direction of the substrate, the first electrode includes
a first portion bonded to the connection terminal,
a second portion surrounding an outer periphery of the first portion, and
a third portion surrounding an outer periphery of the second portion;
a plating film on a surface of the second portion; and
a ceramic protective film made of a ceramic material on a surface of the third portion.

2. The circuit module according to claim 1,
wherein the circuit module satisfies the relationship μ₁>μ₂>μ₃ where μ₁ is a coefficient of thermal expansion of the connection terminal, μ₂ is a coefficient of thermal expansion of the plating film, and μ₃ is a coefficient of thermal expansion of the ceramic protective film.

3. The circuit module according to claim 1,
wherein when viewed in the thickness direction, a width of the third portion is greater than a width of the second portion.

4. The circuit module according to claim 1,
wherein when viewed in the thickness direction, an area of the third portion is larger than a sum of an area of the first portion and an area of the second portion.

5. The circuit module according to claim 1,
wherein the second portion of the first electrode is flush with the one main surface of the substrate, and
the third portion of the first electrode is embedded below the ceramic protective film.

6. The circuit module according to claim 1, further comprising a first resin layer covering the first main surface of the substrate, wherein the connection terminal extends through the first resin layer.

7. The circuit module according to claim 1, wherein the ceramic protective film and the substrate include a same low temperature co-fired ceramic material.

8. The circuit module according to claim 1, wherein a thickness of the third portion of the first electrode gradually decreases in a direction away from the second portion.

9. The circuit module according to claim 1, wherein the substrate further includes a second electrode on the first main surface connected to an electronic component.

10. The circuit module according to claim 9, wherein the electronic component is sealed within a resin layer.

11. The circuit module according to claim 10, wherein the connection terminal is a metal post that extends through the resin layer.

12. The circuit module according to claim 11, wherein the metal post has a cylindrical shape with a diameter of 150 μm to 250 μm.

13. The circuit module according to claim 1, wherein the ceramic protective film surrounds an outer periphery of the third portion.

14. A circuit module, comprising:
a ceramic substrate including an electrode on a main surface thereof;
a metal post bonded to a first portion of the electrode;
a plating film on a second portion of the electrode surrounding the first portion; and
a ceramic protective film disposed on a third portion of the electrode surrounding the second portion, wherein μ1>μ2>μ3 is satisfied, where μ1 is a coefficient of thermal expansion of the metal post, μ2 is a coefficient of thermal expansion of the plating film, and μ3 is a coefficient of thermal expansion of the ceramic protective film.

15. A method of manufacturing a circuit module, the method comprising:
forming a first electrode on a ceramic green sheet;
printing a ceramic protective film paste on a surface of the first electrode such that the ceramic protective film paste defines a third portion of the first electrode;
firing the ceramic green sheet to form a substrate;
forming a connection terminal bonded to a first portion of the first electrode; and
forming a plating film on a second portion of the first electrode positioned between the first portion and the third portion.
